(19) United States
(12) Patent Application Publication
(10) Pub. No.: US 2012/0318785 A1
(43) Pub. Date: Dec. 20, 2012

(54) CERAMIC HEATER

(75) Inventors: Takuma KUSHIHASHI, Annaka-shi (JP); Noboru KIMURA, Annaka-shi (JP); Nobuhiko KODANA, Annaka-shi (JP); Masaki SEKI, Annaka-shi (JP)

(73) Assignee: SHIN-ETSU CHEMICAL CO., LTD., TOKYO (JP)

(21) Appl. No.: 13/495,243

(22) Filed: Jun. 13, 2012

(30) Foreign Application Priority Data
Jun. 15, 2011 (JP) 2011-132890

(51) Int. Cl. H05B 3/10; H05K 13/00

(52) U.S. Cl. 219/548; 29/611

(57) ABSTRACT

A ceramic heater comprising: a support body made of a first non-conductive ceramic material; a heater pattern, which is made of a conductive material and has a terminal junction at each end and is laid on the support body; a coating layer, which is made of a second non-conductive ceramic material and is laid to cover the support body and the heater pattern but not to cover the terminal junctions of the heater pattern; and a lead wire for connecting the terminal junctions to a power source; and this ceramic heater is comprised of that the terminal junctions of the heater are coated with a conductive protective layer; that each heater terminal junction coated with the protective layer and the lead that is connected to the power source are electrically connected to each other via a washer made of a malleable conductive material.

### PRIORITY CLAIMED

The present non-provisional application claims priority, as per Paris Convention, from Japanese Patent Application No. 2011-132890 filed on Jun. 15, 2011, the disclosure of which is incorporated by reference herein in its entirety.

### FIELD OF THE TECHNOLOGY

The present invention relates to a ceramic heater used for heating a semiconductor wafer in a semiconductor production process or for heating a substrate when a thin film is formed thereon by a chemical vapor deposition (CVD) method or a sputtering method or the like.

### BACKGROUND TECHNOLOGY

For heating a semiconductor wafer in a semiconductor manufacturing process or for heating a substrate when a thin film is formed on it by means of a method such as chemical vapor deposition and sputtering, a ceramic(s) heater is used, which comprises a support body made of a sintered substance made from aluminum oxide, aluminum nitride, silicon nitride, boron nitride or the like, in which is buried a metallic heating element in the form of a wire, a foil, a coil, etc. or in which is screen-printed an electrically conductive (hereinafter merely “conductive”) paste containing metal particles or conductive ceramic particles (See, for example, Japanese Unexamined Patent Publication Tokkai 2004-220966 and Tokkai 2004-253799). Among them, in the case of a heater wherein the buried heating element is either a metallic wire, foil or coil, the heater tends to fail to exhibit uniform distribution of heat on account of the difficulty in arranging the metallic wire, foil, or coil in the support body in a compact and precise manner.

Also, in the case of forming a heating element pattern by screen printing, the thickness of the thus formed heating layer tends to lack uniformity, and hence the resultant heater tends to fail to achieve uniform heating. Moreover, there is a possibility that the organic elements contained in the paste used for screen printing or the sintering additives contained in the ceramic sintered body become a source of impurities.

On the other hand, a PG/PBN ceramic heater, which is manufactured in the following manner, is also known: forming a support body out of a pyrolytic boron nitride (PBN) by means of a chemical vapor deposition method, forming a conductive layer of pyrolytic graphite (PG) on the support body by means of a chemical vapor deposition method, shaping the conductive layer into a desired heating element pattern, and then covering up the heating element pattern (conductive layer) with a coating layer of pyrolytic boron nitride by means of chemical vapor deposition (See, Japanese Patent Publication No. 3560456). In this manner, it is easier to obtain the conductive layer which has a uniform film thickness, and thus the resultant ceramic heater would tend to have uniform heating performance, and on top of this, since all of the support body, the conductive layer and the coating layer are manufactured by the chemical vapor deposition method, the conductive layer and the coating layer have higher purities than a ceramic heater made by sintering method, as a result, the semiconductor wafers processed by such a PG/PBN ceramic heater are less liable to be stained with impurities, which is an advantage.

However, in the case of a PG/PBN ceramic heater, as described later, the heating element made of pyrolytic graphite, which is exposed at its terminals, would undergo erosion in an oxidizing atmosphere whereby short circuit is liable to take place, which is a disadvantage.

This disadvantage has been improved by coating the above exposed surfaces of the pyrolytic graphite at the terminals with a heat-resistive conductive film made of a metal having a melting point of 800 degrees centigrade or higher, such as nickel, silver, gold, platinum, tungsten, molybdenum and tantalum, in order to prevent the oxidative consumption on the exposed terminal surfaces of the pyrolytic graphite (Patent document 4). In addition, as for a method for forming such a heat-resistive conductive film, examples include a thermal evaporation deposition method, an electron beam deposition method, and a sputtering method.

A top plan view and a cross sectional view of the above PG/PBN heater are, respectively, shown in FIG. 1 (a) and (b), and the heater is composed of a support body 1 made of pyrolytic boron nitride, a heating element pattern 2 made of pyrolytic graphite, and a CVD deposited coating layer 3 made of pyrolyitic boron nitride covering the heating element pattern. In order to put the heater operative, each of the terminals of the heating element pattern 2 is formed with a through hole 4, and those portions of the coating layer 3 which are in the vicinity of the respective through holes 4 are removed to expose the heating element 2, and thus terminal junctions 5 are prepared for connection to a power source. The heater is completed as a product when lead wires from the power source are fixed to the terminal junctions 5 by means of a bolt, a nut, a washer, etc. made of a metal or a carbonaceous material such as graphite and carbon/carbon composite.

FIG. 2 (a) and (b) illustrate an example of how a PG/PBM heater is connected to a power source. FIG. 2 (a) is a perspective view and FIG. 2 (b) is a cross sectional view. To an upper side of each exposed terminal junction 5 of the heating element 2 on one hand and to a back side of each junction 5 on the other hand is attached each a carbonaceous washer 6 made of flexible graphite, and to each washer 6 is attached a metallic washer 7, and an end of a crimp-style terminal 10 is put to the back-side washer 7, and these are penetrated by a bolt 8 and fixed by nuts 9. The other end of the crimp-style terminal 10 is connected to a lead (wire) 11, which is connected to a power source (not shown).

Those portions of the surface of the heating element 2 which are exposed at the terminal junctions 5 and the faces of the metallic washers 7 are not exactly flat. There are more or less infinitesimal irregularities depending on the precision of machine finish they received. Therefore, if the metallic washers 7 are directly put to the exposed heating elements 2 at the respective terminal junctions 5, only partial connection is established at protruding points of the surfaces of the metallic washers 7 and the heating elements 2, so that only insufficient effective connection area is obtained and, as a result, the electric current would concentrate at the limited connection areas whereby extraordinary heat is created there, causing electric discharge, which can damage the terminal junctions 5 to an extent that it becomes impossible to supply electricity to the PG/PBN heater for heating.

The carbonaceous washers 6 are used to prevent this problem. The washer 6 is placed between the exposed surface of the heating element 2 and the metallic washer 7 at each junction 5, and when squeezed by the bolt 8 and the nuts 9, the carbonaceous washer 6 made of flexible graphite undergoes depression and is thus molded between the exposed surface of the heating element 2 and the metallic washer 7 so that it fills in the infinitesimal irregularities of the surfaces of these elements 2 and 7. Consequently, sufficient connection areas are obtained between the exposed surface of the heating element 2 and the carbonaceous washer 6 and also between the carbonaceous washer 6 and the metallic washer 7, thus a broad electric passage between the exposed surface of the heating element 2 and the metallic washer 7 is secured at each of the terminal junctions 5.

Now, in a method of metal organic chemical vapor deposition (MOCVD), which is a conventional means for growing a crystal out of a group III-V nitride compound semiconductor substance such as GaN, trimethyl gallium (TMG) is used as the source gas for the group III element, and ammonia gas is used as the nitrogen source. And a sapphire plate is usually used for the substrate on which the crystal is grown, and raw gas supply nozzles and a susceptor on which the substrate is positioned are installed in a reaction vessel in which the MOCVD method is carried out. The sapphire substrate positioned on the susceptor is usually heated to a temperature of 1000 degrees centigrade or higher by a heating means such as electric resistance heater and high frequency induction heater, and TMG and ammonia gas are supplied with a carrier gas of hydrogen gas toward the sapphire substrate, whereby a GaN crystal is grown on the sapphire substrate.

As suggested above, in the case of growing a crystal of a group III-V nitride compound semiconductor substance such as GaN by means of the MOCVD method, the reducing atmosphere (decomposed ammonia gas and hydrogen gas) is created inside the reaction vessel. As is known, when heated to a temperature of 1000 degrees centigrade or higher, ammonia gas undergoes a thermal decomposition and creates nitrogen on one hand, which becomes the nitrogen source for the GaN crystal, and on the other hand creates hydrogen gas. Also, the hydrogen gas which is used as the carrier gas reacts with carbon to create CH₄ at a temperature of 900 degrees centigrade or higher and thus depletes carbon. For this reason, if a PG/PBN heater is used to heat the substrate in the MOCVD method, the heater pattern made of pyrolytic graphite which is exposed at its terminal junctions and the carbon washers are consumed by the hydrogen so that the connection failure occurs at the terminal junctions and such junctions would lead to major troubles.

This problem cannot be solved by the above-mentioned conventional method (Japanese Utility Model Publication H05 (1993)-90880), wherein the exposed surface of the pyrolytic graphite heater at the terminal junctions is coated with a heat-resistive conductive film made of a metal having a melting point of 800 degrees centigrade or higher, such as nickel, silver, gold, platinum, tungsten, molybdenum and tantalum. This is because the carbon washers are consumed by hydrogen.

### SUMMARY OF THE INVENTION

Therefore, the first object of the present invention is to provide a ceramic heater used for crystal growth based on a MOCVD method or the like, which is able to use preferably in a reducing atmosphere.

The second object of the present invention is to provide a method for manufacturing a ceramic heater which is able to use preferably in a reducing atmosphere.

The third object of the present invention is to provide a washer used for a ceramic heater which is able to use preferably in a reducing atmosphere.

The above-mentioned objects of the present invention were accomplished by a ceramic heater, by a method for manufacturing the same ceramic heater and by a washer used for the same ceramic heater—this ceramic heater comprises: a support body made of an electrically non-conductive (hereinafter merely “non-conductive”) ceramic material; a heater pattern, which is made of a conductive material and has a terminal junction at each end and is laid on the support body; a coating layer, which is made of a non-conductive ceramic material and is laid to cover the support body and the heater pattern but not to cover the terminal junctions of the heater pattern; and a lead wire for connecting the terminal junctions to a power source; and this ceramic heater is characterized in that the terminal junctions of the heater are coated with a conductive protective layer, and in that each heater terminal junction coated with the protective layer and the lead that is connected to the power source are electrically connected to each other via a washer made of a malleable conductive material.

In the present invention it is preferable that the conductive protective layer and the conductive malleable washer are resistive to a reducing atmosphere, and especially preferable that they are resistive to one or more of such reducing atmospheres as ammonia gas, hydrogen gas, a mixture gas of ammonia gas and hydrogen gas, and a mixture gas of nitrogen gas and hydrogen gas.

In the present invention, it is preferable that the non-conductive ceramic support body is made of pyrolytic boron nitride and that the conductive heater pattern is made of pyrolytic graphite, and that the non-conductive ceramic coating layer is made of pyrolytic boron nitride.

### EFFECTS OF THE INVENTION

The ceramic heater according to the present invention is capable of a long dependable use even if it is used to heat a base plate in the MOCVD method, for the reason that the terminal junctions of its heating pattern are not consumed by the reducing atmosphere.

### BRIEF EXPLANATION OF THE DRAWINGS

FIG. 1 is an explanatory drawing of a PG/PBN heater, in which part (a) is a plan view and part (b) is a cross sectional view.

FIG. 2 is an explanatory drawing describing how a PG/PBN heater is connected to a power source, in which part (a) is a perspective view and part (b) is a cross sectional view.

FIG. 3 is a conceptual cross sectional view of a ceramic heater's terminal junction of the present invention, in which part (a) shows an embodiment in which only the exposed surface of the terminal junction is coated with a protective layer, and part (b) shows an embodiment in which a part of the insulation layer as well as the exposed surface of the terminal junctions is coated with the protective layer.

FIG. 4 is a drawing to show how a PG/PBN heater of the present invention is connected to a power source, in which part (a) is a perspective view and part (b) is a cross sectional view.

FIG. 5 is an explanatory drawing of a ceramic heater made in an example of the present invention, in which part (a) illustrates a heater pattern and part (b) illustrates the ranges across which the protective layer is formed.

### MODES FOR CARRYING OUT THE INVENTION

The present invention is most characteristic, among others, in that the terminal junctions of the heater pattern are coated with a conductive protective layer, and each terminal junction coated with the protective layer and a lead that is connected to the power source are coupled to each other via a washer made of a malleable conductive material.

The support body made of a non-conductive ceramic material used in the present invention can be selected from any conventionally known non-conductive ceramic materials, and in the present invention a specially preferred one is pyrolytic boron nitride. Such a support body made of pyrolytic boron nitride can be formed by the chemical vapor deposition method using boron tri-chloride and ammonia, for example, as the raw materials. The thickness of the pyrolytic boron nitride support body used in the present invention is not limited in particular, but it is preferably 0.5 to 3 mm, and more preferably 1 to 2 mm. If the thickness of the pyrolytic boron nitride support body is less than 0.5 mm, the support body becomes liable to break as the ceramic heater is handled during its production and use; if the thickness is more than 3 mm, it requires a substantially longer time for the chemical vapor deposition method to complete such a thickness, so that the manufacturing cost becomes much higher.

The conductive layer to be laid on the support body of pyrolytic boron nitride is preferably made of pyrolytic graphite in the present invention. This conductive layer of pyrolytic graphite is preferably formed by a chemical vapor deposition method using a hydrocarbon gas such as methane and propane as the raw material. The reason for this is that by using a chemical vapor deposition method, the resulting thickness of the conductive layer becomes more uniform than in the case of applying a conductive paste by screen printing. There is no limit on the thickness of the pyrolytic graphite conductive layer, but it is preferably in a range from 10 to 300 micrometers, and it would be better if it is in a range from 30 to 150 micrometers. In the present invention, an appropriate thickness is selected from the above ranges based on careful considerations including the importance of achieving a quick arrival of the heater temperature at an aimed temperature while maintaining a uniform distribution of the heat, the power source capacity, and the shape of the heater pattern. After the formation of the pyrolytic graphite conductive layer, this layer is machined into a heater pattern.

The coating layer laid over the heater pattern made of pyrolytic graphite can be any of conventionally implemented non-conductive layers, but in the present invention a more preferable choice is to adopt a pyrolytic boron nitride layer which is formed from boron trichloride and ammonia by a chemical vapor deposition method. As for a coating layer made of pyrolytic boron nitride, there is no limitation on the layer's thickness in particular, but it is preferably 20 to 300 micrometers, and more preferably 50 to 200 micrometers. When the thickness of the coating layer made of pyrolytic boron nitride is less than 20 micrometers, there is an increased risk of suffering insulation breakdown, and when it is more than 300 micrometers, it becomes easier to detach, which is a problem.

In the next step, a through hole 4 is made at each end of the heater pattern 2 in order that a screw or a bolt is passed in it for connection to the power source, and that portions of the coating layer 3 in the vicinities of the through holes 4 are removed by machining to partially expose the heater element 2; thereby terminal junctions 5 are prepared for connection to the power source.

In the present invention, a protective layer resistive to gases in the atmosphere (such as ammonia gas and hydrogen gas) is formed over the terminal junctions of the PG/PBN heater pattern formed in the manner described above. In the present invention this protective layer is preferably made of a metal, especially tungsten and platinum are more preferred, to make the protective layer. Tungsten and platinum have comparatively high melting points, and do not undergo a reaction or fixation, at 1300 degrees centigrade or so, with pyrolytic boron nitride or pyrolytic graphite, by which the inventive ceramic heater is constituted. In fact, tungsten is inert in a dry ammonia gas as well as in a dry hydrogen gas up to temperatures as high as its melting point, and platinum is capable of being used as the material for a constituent of a type R thermo couple or a type S thermo couple, which are used in the hydrogen atmosphere of temperatures 1100 degrees centigrade or so.

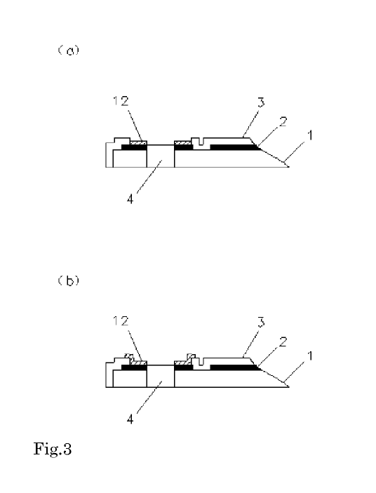

In the present invention, the PG/PBN heater pattern is masked by a masking means, except for the terminal junctions of the heater pattern, and then, by means of a method selected from an ion plating method, a sputtering method, a chemical vapor deposition method and an atomic layer deposition (ALD) method, a protective layer 12 having a resistivity to ammonia gas or hydrogen gas is formed either covering only the terminal junctions, as shown in FIG. 3 (a), or covering the terminal junctions plus their fringing areas, as shown in FIG. 3 (b). If the protective layer 12 is to be formed in the manner as shown in FIG. 3 (b), the opening of the masking means will have a greater diameter than that of the terminal junction, so that even if the masking means is slightly misplaced at the time of the formation of the protective layer, it would be unlikely that there exists a portion of the exposed heater pattern that is not covered with the protective layer. Now, herein, by “masking means” we mean a stencil to cover the portions where it need not be coated with the protective layer during its formation.

If the protective layer is formed by means of either an ion plating method, a sputtering method, a chemical vapor deposition method or an atomic layer deposition (ALD) method, it is possible to obtain a protective layer having higher density and greater adhesion than is the case wherein a thermal chemical vapor deposition method or an electron beam deposition method is adopted, so that the resultant protective layer would be a more appropriate one for protecting the terminal junctions of the heater pattern of the ceramic heater for use in a reducing atmosphere of temperatures of 1000 degrees centigrade or higher; but this does not mean that the ceramic heater of the present invention is exclusively used under such a condition.

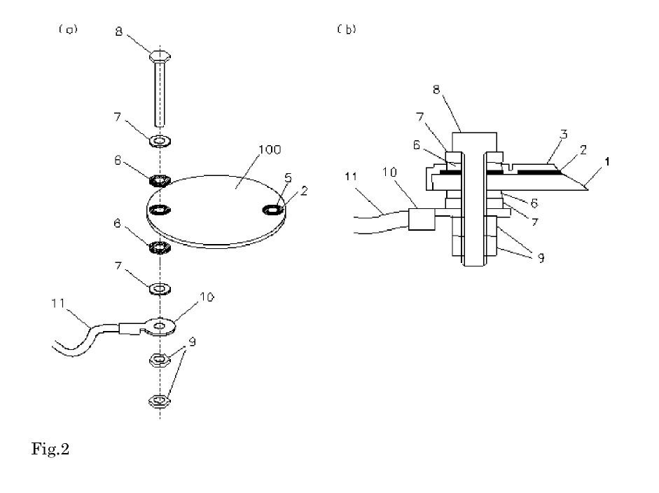

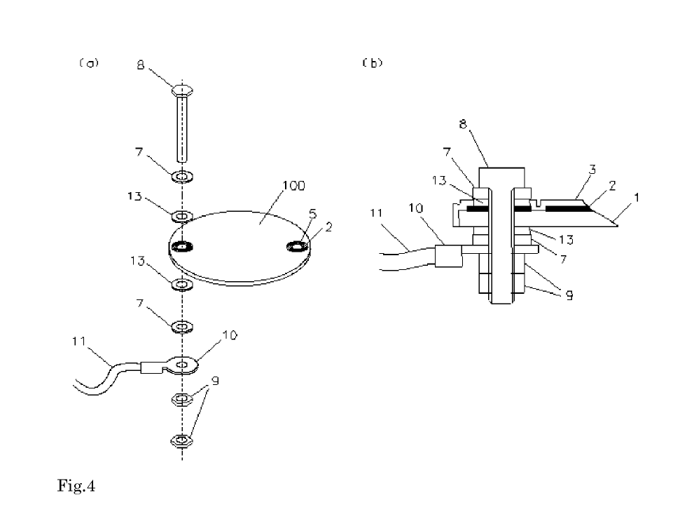

In order to use the thus manufactured ceramic heater, in which the terminal junctions of the heater pattern are covered with protective layer resistive to reducing atmosphere, in a reducing atmosphere of 1000 degrees centigrade or higher, the ceramic heater may be connected to a power source in a manner as shown in FIG. 4 (a) and (b) or in a manner akin to this. The connection manner shown in FIG. 4 (a) and (b) is basically the same as the one shown in FIG. 2 except that the carbonaceous washers 6, which are consumed in a reducing atmosphere—as explained earlier—are replaced by platinum washers 13. Platinum is soft and malleable so that by tightening these washers upon the terminal junctions of the heater pattern by means of screws, bolts, nuts or the like, it is possible to obtain highly conductive connection with the exposed terminal junctions of the heater pattern. There is no particular limit on the thickness of the platinum washer, but it is preferably 0.1 mm or thinner; but it is specially recommended to use a platinum washer having a thickness from 0.03 to 0.1 mm. If a designed thickness is smaller than 0.03 mm, it is difficult to make such a washer, and on the other hand, if the thickness is greater than 0.1 mm, there is no gain in effect while the cost increases with the thickness.

The screws, bolts, nuts, etc. used for electric connection toward the power source are preferably made of tungsten, for it is cheaper than platinum. They must not be made of a carbonaceous material such as graphite and carbon/carbon composite. They will be consumed in a reducing atmosphere of 1000 degrees centigrade or higher like pyrolytic graphite and carbonaceous washer.

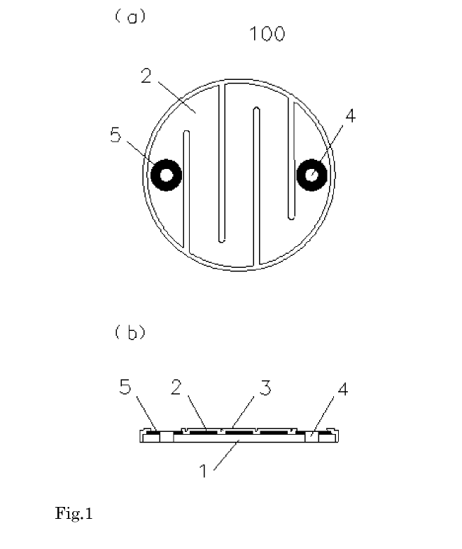

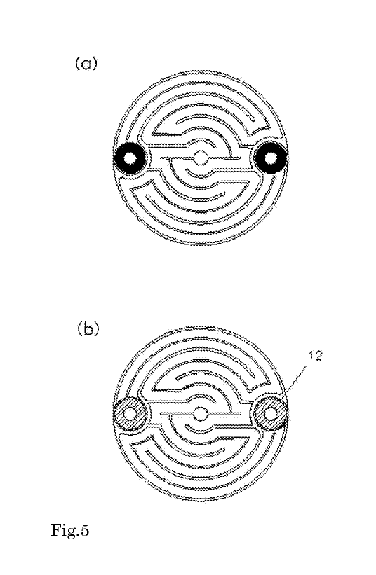

Now, as for the construction of the terminal junctions of the heater pattern of the ceramic heater of the present invention, we have disclosed examples shown in FIG. 1 (a) and (b), FIG. 3 (a) and (b), and FIG. 5 (a) and (b), but these do not limit the scope of the present invention. In the examples, through holes are made and around the through holes the heater pattern is exposed in a shape of a concentric ring, but the invention is not limited by this construction. In addition, as an example of the way in which the inventive ceramic heater is connected to the power source, we disclosed one as shown in FIG. 4 (a) and (b), but the invention is not limited by this example.

Moreover, as for the lead, we disclosed one in the form of a wire with a crimp-style terminal at one end, but the lead may not be wiry but may be in a shape of a circular column or a plate, for example. So long as it makes a passage that leads sufficient electricity from the power source to the heater, any lead that may be without a crimp-style terminal or one that may be equipped with a device of any shape having a function similar to that of a crimp-style terminal, are all included in the meaning of the lead of the present invention.

Furthermore, as the electrically conductive washer, we disclosed ones having an ordinary washer shape, but the present invention does not require them to be so. In the present invention, washers having shapes that are modified to meet the respective construction of the terminal junctions so as to properly function as conductive washers are included in the concept of the washer of the present invention.

We will now explain the present invention by using examples but they shall not be construed to limit the scope of the present invention.

### Example 1

First, by reacting ammonia, which was supplied at a rate of 4 liters per minute, with boron trichloride, which was supplied at a rate of 2 liters per minute, under a pressure of 10 Torr and at a temperature of 1850 degrees centigrade, the inventors made a disc of pyrolytic boron nitride measuring 60 mm in diameter and 1.0 mm in thickness, and this was used as the support body for a ceramic heater. Next, by thermally decomposing methane, which was supplied at a rate of 3 liters per minute under a pressure of 5 Torr and at a temperature of 1750 degrees centigrade, the inventors formed a 50-micrometer-thick pyrolytic graphite layer on the disc, and by means of mechanical tooling a heater pattern was cut out. Then, on this heater a reaction was carried out between ammonia, which was supplied at a rate of 5 liters per minute, and boron trichloride, which was supplied at a rate of 2 liters per minute, under a pressure of 10 Torr and at a temperature of 1890 degrees centigrade, whereby the disc was coated integrally with a monolithic insulating layer of pyrolytic boron nitride.

Next, a through hole was made at each end of the heater pattern, and the heater pattern was exposed by removing the coating layer in the vicinities of the through holes, thereby creating terminal junctions for connection to the power source, and thus a PG/PBN heater as shown in FIG. 5 (a) was obtained. The diameter of the terminal junctions was made as 10 mm. Next, whole this PG/PBN heater pattern other than its terminal areas was masked with a stainless steel (SUS) stencil, and a 0.5-micrometer-thick protective layer 12 of tungsten was formed on the terminal areas and their 0.5-mm wide fringe areas by the ion plating method, as shown in FIG. 5 (b).

The thus obtained ceramic heater was set in a vacuum chamber, and, as shown in FIG. 4 (a) and (b), the heater terminal junction 5 and the lead 11, which leads to the power source, were electrically connected to each other via a platinum washer 13, and thus the ceramic heater of the present invention was completed. The diameters of the platinum washers were made as 9.8 mm. The thus prepared ceramic heater was turned on electricity in a near-vacuum atmosphere of 1 Pa pressure, and when the temperature reached 1300 degrees centigrade, ammonia gas was supplied to the chamber at a flow rate of 5 liters per minute, and the pressure in the chamber was controlled to 1000 Pa. With the things as they were, the temperature of the ceramic heater was maintained at 1300 degrees centigrade and the current was ceased after 120 hours, and the heater was cooled. After the cooling, the ceramic heater was taken out of the chamber, and the terminal junctions of the heater were inspected, and it was found that the tungsten protective layer remained on the terminal conjunctions and there was no evidence that the heater had suffered consumption at its terminal conjunctions.

### Comparative Example 1

Except that a carbon washer was used in place of the platinum washer used in Example 1, all the details of Example 1 were carried out to manufacture a ceramic heater of Comparative Example 1. In the same manner as in Example 1, the thus obtained ceramic heater was maintained in the chamber and kept at 1300 degrees centigrade, but the breaker of the power source worked after 20 minutes. After the cooling, the ceramic heater was taken out of the chamber and the terminal junctions of the heater were inspected and it was found that the terminal areas were burnt, possibly owing to the electric discharge, so badly that they could no longer turn on.

### Comparative Example 2

Except that the formation of the protective layer resistive to ammonia gas and hydrogen gas was not conducted on the terminals, all the details of Example 1 were carried out to manufacture a ceramic heater of Comparative Example 2. Observing the same procedure as in Example 1, except that the retaining time was 26 hours, the thus obtained ceramic heater was maintained at 1300 degrees centigrade in the chamber; after the current was stopped, the heater was let to cool. After the cooling, the ceramic heater was brought out of the chamber, and the heater's terminal junctions were inspected, and there was no evidence that junctions had consumed in the vicinities of the through holes. However, the outer peripheries of the terminal junctions were found to have consumed by about 25 micrometers, and it is suspected that the ammonia gas had entered through narrow clefts between the PBN coating layer and the platinum washer because the diameter of each terminal junction was 10 mm but the diameter of the platinum washer was only 9.8 mm.

### Comparative Example 3

Except that the formation of the protective layer resistive to both ammonia gas and or hydrogen gas was not conducted on the terminal junctions, all the details of Comparative Example 1 were carried out to manufacture a ceramic heater of Comparative Example 3. Observing the same procedure as in Comparative Example 1, the thus obtained ceramic heater was maintained at 1300 degrees centigrade in the chamber, but the breaker of the power source worked after 10 minutes. After the cooling, the ceramic heater was taken out of the chamber and the terminal junctions of the heater pattern were inspected. It was found that the terminal areas were burnt, possibly owing to the electric discharge, so badly that they could no longer turn on.

### INDUSTRIAL APPLICABILITY

The ceramic heater of the present invention does not suffer a failure at the terminal junctions that is caused by the erosive effect of the reducing atmosphere, so that it can be used for a long time dependably and therefore is industrially very useful.

### EXPLANATION OF THE REFERENCE NUMERALS

100: ceramic heater (PG/PBN heater)
1: support body
2: heater (pattern)
3: coating layer
4: through hole
5: terminal junction
6: carbon washer made of flexible graphite
7: metallic washer
8: bolt
9: nut
10: crimp-style terminal
11: lead wire
12: protective layer
13 platinum washer

1. A ceramic heater comprising: a support body made of a first non-conductive ceramic material; a heater pattern, which is made of a conductive material and has a terminal junction at each end and is laid on said support body; a coating layer, which is made of a second non-conductive ceramic material and is laid to cover said support body and said heater pattern but not to cover said terminal junctions of said heater pattern; and a lead wire for connecting said terminal junctions to a power source; said ceramic heater is comprised of that said terminal junctions of the heater pattern are coated with a conductive protective layer; that each one of said heater terminal junctions and said lead are electrically connected to each other via a washer made of a malleable conductive material.

2. A ceramic heater as claimed in claim 1, wherein the said conductive protective layer is resistive to a reducing atmosphere.

3. A ceramic heater as claimed in claim 1, wherein the said malleable conductive material is resistive to a reducing atmosphere.

4. A ceramic heater as claimed in claim 1, wherein the said reducing atmosphere is consisting of ammonia gas, hydrogen gas, a mixture gas of ammonia gas and hydrogen gas, or a mixture gas of nitrogen gas and hydrogen gas.

5. A ceramic heater as claimed in claim 1, wherein the said conductive protective layer coating prepared on the terminal junctions is made of tungsten or platinum.

6. A ceramic heater as claimed in claim 1, wherein the said first non-conductive ceramic material to make the support body is a pyrolytic boron nitride.

7. A ceramic heater as claimed in claim 1, wherein the said conductive material to make the said heater pattern is pyrolytic graphite.

8. A ceramic heater as claimed in claim 1, wherein the said second non-conductive ceramic material to make the coating layer is pyrolytic boron nitride.

9. A ceramic heater as claimed in claim 1, wherein the said washer is made of platinum.

10. A method of manufacturing the ceramic heater of claim 1, comprising that the said conductive protective layer is prepared on the said terminal junctions of the said heater pattern by means of a method selected from an ion plating method, a sputtering method, a chemical vapor deposition method and an atomic layer deposition (ALD) method.

11. A washer made of platinum used for the ceramic heater of claim 1.
